(19) United States
(12) Patent Application Publication
(10) Pub. No.: US 2012/0119391 A1
(43) Pub. Date: May 17, 2012

(54) SEMICONDUCTOR PACKAGE AND MANUFACTURING METHOD THEREOF

(75) Inventors: Naoyuki KOIZUMI, Nagano (JP); Kenta Uchiyama, Nagano (JP)

(73) Assignee: SHINKO ELECTRIC INDUSTRIES CO., LTD., Nagano (JP)

(21) Appl. No.: 13/295,158

(22) Filed: Nov. 14, 2011

(30) Foreign Application Priority Data
Nov. 15, 2010 (JP) 2010-254870

(51) Int. Cl. H01L 23/48; H01L 21/56

(52) U.S. Cl. 257/782; 438/127; 257/E23.01; 257/E21.502

(57) ABSTRACT

A semiconductor package includes a support member having a concave portion formed in one surface thereof. A semiconductor chip is accommodated in the concave portion so that a circuit formation surface of the semiconductor chip is exposed on a side of the one surface of the support member. A wiring structure including a wiring layer electrically connected to the semiconductor chip is formed on the circuit formation surface of the semiconductor chip and the one surface of the support member. A portion of the support member including the one surface is made of silicon or borosilicate glass.

### CROSS-REFERENCE TO RELATED APPLICATIONS

This application is based upon and claims the benefit of priority of the prior Japanese Patent Application No. 2010-254870, filed on Nov. 15, 2010, the entire contents of which are incorporated herein by reference.

### FIELD

The present invention relates to a semiconductor package having a wiring structure electrically connected to a semiconductor chip and a manufacturing method of such a semiconductor package.

### BACKGROUND

Conventionally, there is suggested a semiconductor package including a support member having a concave portion formed on one side thereof to accommodate a semiconductor chip. The semiconductor chip is accommodated in the concave portion so that the primary surface (circuit formation surface) is exposed on the one side of the support member in a face-up state. Insulation layers and wiring layers are laminated alternately on the primary surface of the semiconductor chip and the one side of the support member.

In the above-mentioned semiconductor package, the support member is formed, for example, of a metal plate. Specifically, a support member made of, for example, a copper plate is prepared, and a concave portion to accommodate a semiconductor chip is formed in the prepared support member by an etching method or the like. Alternatively, a support member is formed of a nickel plate having an extremely thin gold plated layer formed thereon and a copper plated layer formed on the gold plate layer. The copper plated layer has a thickness as large as a semiconductor chip. A penetrating opening penetrating the copper plated layer is formed in the copper plated layer in order to expose the gold plated layer underneath the copper plated layer so that a concave portion is defined by inner side surfaces of the penetrating opening and the exposed surface of the gold plated layer.

Japanese laid-Open Patent Application No. 2009-194322 discloses a conventional semiconductor package.

If a metal is used to form a support member, it becomes difficult to miniaturize the wiring patterns formed on the primary surface of the semiconductor chip and one side of the support member because the one side of the support member is not a smooth and flat surface (the surface roughness of the one side of the support member is large). Additionally, if metals are joined to each other via a gold plated layer or an adhesive layer, one side of the support member may incline relative to the primary surface of the semiconductor surface because it is difficult to uniformize the thicknesses of the gold plated layer and the adhesive layer. Accordingly, accuracy in exposure and development to form wiring patterns on the one side of the support member is deteriorated, which results in difficulty in miniaturizing the wiring pattern.

### SUMMARY

There is provided according to an aspect of the invention a semiconductor package, comprising: a support member having a concave portion formed in one surface thereof; a semiconductor chip accommodated in the concave portion so that a circuit formation surface of the semiconductor chip is exposed on a side of the one surface of the support member; and a wiring structure including a wiring layer electrically connected to the semiconductor chip, the wiring structure being formed on the circuit formation surface of the semiconductor chip and the one surface of the support member, wherein a portion of the support member including the one surface is made of silicon or borosilicate glass.

There is provided according to another aspect a manufacturing method of a semiconductor package, comprising: preparing a support member having a concave portion formed in one surface thereof, a portion of the support member including the one surface being made of silicon or borosilicate glass; accommodating a semiconductor chip in the concave portion of the support member so that a circuit formation surface of the semiconductor chip is exposed on a side of the one surface of the support member; and forming a wiring structure on the circuit formation surface of the semiconductor chip and the one surface of the support member, the wiring structure including a wiring layer electrically connected to the semiconductor chip.

It is to be understood that both the foregoing general description and the following detailed description are exemplary explanatory only and are not restrictive of the invention, as claimed.

### BRIEF DESCRIPTION OF DRAWINGS

FIG. 1 is a cross-sectional view of a semiconductor package according to a first embodiment of the present invention;

FIG. 2A is a plan view of a support member used in a manufacturing process of the semiconductor package according to the first embodiment;

FIG. 2B is a cross-sectional view of the support member taken along a line A-A of FIG. 2A;

FIG. 3 is a cross-sectional view of a semiconductor chip to be incorporated into the semiconductor package according to the first embodiment;

FIG. 4 is a cross-sectional view of the support member having the semiconductor chips accommodated in concave portions of the support member;

FIG. 5 is a cross-sectional view for explaining a step of filling a resin between each semiconductor chip and inner surfaces of each concave portion;

FIG. 6 is a cross-sectional view for explaining a step of forming a first insulation layer on the support member and the semiconductor chips;

FIG. 7 a cross-sectional view for explaining a step of forming first via holes in the first insulation layer;

FIG. 8 is a cross-sectional view for explaining a step of forming a first wiring layer on the first insulation layer;

FIG. 9 is a cross-sectional view for explaining a step of sequentially forming a second insulation layer, a second wiring layer, a third insulation layer and a third wiring layer on the first wiring layer;

FIG. 10 is a cross-sectional view for explaining a step of forming a solder resist layer on the third insulation layer;

FIG. 11 is a cross-sectional view for explaining a step of forming external connection terminals on the third wiring layer;

FIG. 12 is a cross-sectional view for explaining a step of individualizing semiconductor packages;

FIG. 13 is a cross-sectional view of a semiconductor package according to a second variation of the first embodiment;

FIG. 14 is a cross-sectional view for explaining a step of filling a resin and forming a first insulation layer on the support member and the semiconductor chips;

FIG. 15 is a cross-sectional view of a semiconductor package according to a third variation of the first embodiment;

FIG. 16 is a cross-sectional view for explaining a step of filling a resin between each semiconductor chip and inner surfaces of each concave portion;

FIG. 17 is a cross-sectional view for explaining a step of forming a first insulation layer on the support member and the semiconductor chips;

FIG. 18 is a cross-sectional view of a semiconductor package according to a second embodiment of the present invention;

FIG. 19A is a plan view of a support member used in a manufacturing process of the semiconductor package according to the second embodiment;

FIG. 19B is a cross-sectional view of the support member taken along a line A-A of FIG. 19A;

FIG. 20 is a cross-sectional view of a semiconductor package according to a third embodiment of the present invention;

FIG. 21A is a plan view of a support member used in a manufacturing process of the semiconductor package according to the third embodiment; and

FIG. 21B is a cross-sectional view of the support member taken along a line A-A of FIG. 21A.

### DESCRIPTION OF EMBODIMENT(S)

Preferred embodiments of the present invention will be explained with reference to the accompanying drawings.

### First Embodiment

A description is given below of a structure of a semiconductor package according to a first embodiment.

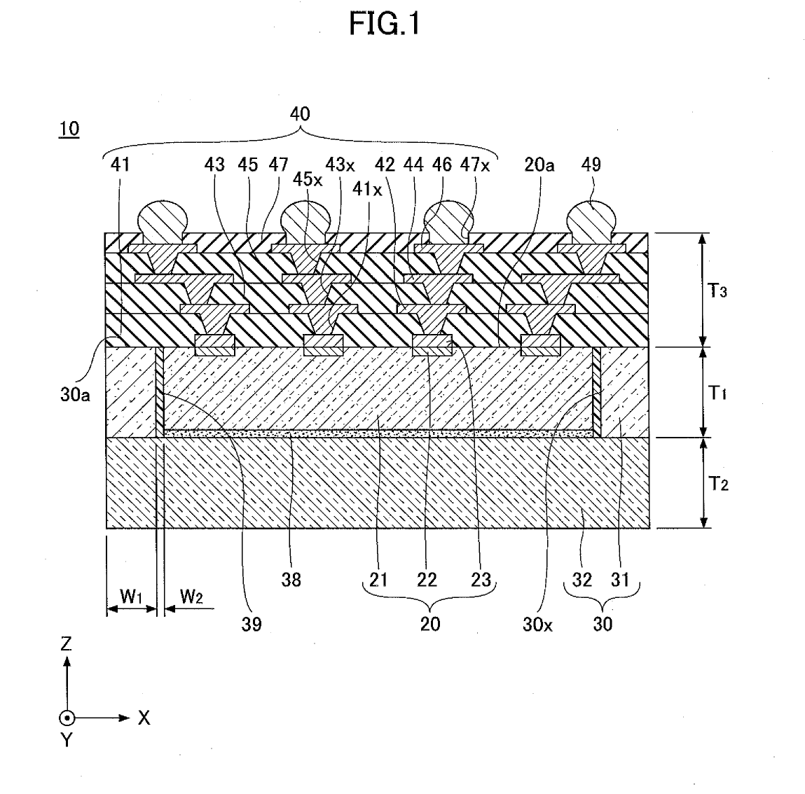

FIG. 1 is a cross-sectional view illustrating a semiconductor package according to a first embodiment. With reference to FIG. 1, a semiconductor package 10 includes a semiconductor chip 20 and a support member 30 together used as a base material. A wiring structure 40 is formed on the base material, and external connection terminals 49 are formed on the wiring structure 40.

The planar shape of the semiconductor package 10 is, for example, a rectangular shape. The size of the rectangular shape can be, for example, a width of 15 mm (X direction)×a depth of 15 mm (Y direction)×a thickness of 0.8 mm (Z direction). A description will be given in detail below of the semiconductor chip 20, the support member 30 and the wiring structure 40, which together constitute the semiconductor package 10. It should be noted that a circuit formation surface of the semiconductor chip 20 may be referred to as a primary surface. Additionally, a surface of the semiconductor chip 20, which is opposite to the primary surface and substantially parallel to the primary surface, may be referred to as a back surface. Further, a surface of the semiconductor chip 20, which is substantially perpendicular to the primary surface and the back surface, may be referred to as a side surface.

The semiconductor chip 20 includes a semiconductor substrate 21, electrode pads 22 and projection electrodes 23. The semiconductor chip 20 is accommodated in a concave portion 30x of the support member 30 with a double-sided adhesive 38 applied to the back surface of the semiconductor chip 20. A resin part 39 is formed by filling a resin into gaps between each of the side surfaces of the semiconductor chip 20 and a respective one of inner surfaces of the concave portion 30x. The thickness T1 of the semiconductor chip 20 (including the double-sided adhesive 38) can be set to, for example, about 300 μm to 500 μm.

A semiconductor integrated circuit (not illustrated in the figure) is formed on the primary surface of the semiconductor substrate 21, which is farmed of, for example, silicon (Si), germanium (Ge), etc. The electrode pads 22 are formed in the semiconductor chip 20 on the side of the primary surface 20a. The electrode pads 22 are electrically connected to the semiconductor integrated circuit. As a material of the electrode pads 22, aluminum (Al) or the like may be used. A lamination of copper (Cu) and aluminum (Al) stacked in that order or a lamination of copper (Cu), aluminum (Al) and silicon (Si) stacked in that order may also be used to form the electrode pads 22.

The projection electrodes 23 are formed on the respective electrode pads 22. For example, copper (Cu) posts having a cylindrical shape may be used as the projection electrodes 23. The diameter of each of the projection electrodes 23 can be set to, for example, about 50 μm. The height of each of the projection electrodes 23 can be set to, for example, about 5 μm to about 10 μm. The pitch of the adjacent projection electrodes 23 can be set to, for example, about 100 μm. The projection electrodes 23 are not necessarily provided on the electrode pads 22. In such a case, the electrode pads 22 serve as electrodes which are electrically connected a first wiring layer 42 of the wiring structure 40.

The concave portion 30x is formed in one surface 30a of the support member 30. More specifically, the support member 30 includes a first member 31 and a second member 32 wherein the first member 31 is joined to a surface of the second member 32 having a flat-plate shape by anodic bonding. The first member 31 is provided with a penetrating opening having a substantially rectangular planar shape so that the concave portion 30x is defined by the inner surfaces of the penetrating opening and a surface of the second member 32 exposed in the penetrating opening. The semiconductor chip 20 is accommodated in the concave portion 30x.

The surface 30a of the support member 30 (the surface of the first member 31 contacting the first insulation layer 41) is substantially in the same plane as the primary surface 20a of the semiconductor chip 20. The thickness T1 of the first member 31 (which is approximately equal to a sum of the thickness of the semiconductor chip 20 and the thickness of the double-sided adhesive 38) can be set to, for example, about 300 μm to about 500 μm.

The thickness T2 of the second member 32 can be set to about 300 μm to about 500. The width W1 of one side of the support member 30 can be set to about 200 μm to about 500 μm.

Silicon or borosilicate glass can be used as a material of the first member 31. Silicon, borosilicate glass or metal can be used as a material of the second member 32. However, because the first member 31 and the second member 32 are to be joined to each other by anodic bonding, at least one of the first member 31 and the second member 32 must be formed of borosilicate glass. That is, if the material of the first material 31 is borosilicate glass, the material of the second member 32 can be silicon or metal. If the material of the first member 31 is silicon, the material of the second member 32 must be borosilicate glass. Because the borosilicate glass contains metal ions such as sodium ions, etc., the borosilicate glass can be joined to silicon or metal by anodic bonding.

As mentioned above, by using the support member 30 including the first member 31 and the second member 32 joined to each other by anodic bonding, there is no problem caused by unevenness of a gold plated layer or an adhesive layer, which may be used to join the first member 31 and the second member 32. Thus, a degree of inclination of the surface 30a of the support member 30 with respect to the primary surface 20a of the semiconductor chip 20 can be reduced. Thereby, accuracy in exposure and development when forming wiring patterns is improved, which enables miniaturization of the wiring patterns formed on the primary surface 20a of the semiconductor chip 20 and the surface 30a of the support member 30.

Silicon or borosilicate glass which is used as the material of the first member 31 has a surface smoother than a surface of a metal. This is also a factor of enabling miniaturization of the wiring patterns formed on the primary surface 20a of the semiconductor chip 20 and the surface 30a of the support member 30. It should be noted that the miniaturization of the wiring patterns referred to in the present application means formation of fine wiring patterns having L/S (line/space)=3 μm/3 μm.

Moreover, by using silicon or borosilicate glass as a material of the first member 31, it becomes possible to make the coefficient of thermal expansion (CTE) of the first member 31 to be approximately equal to the coefficient of thermal expansion (CTE) of the semiconductor chip 20, thereby reducing warpage or distortion in the completed semiconductor package 10. Here, the coefficient of thermal expansion (CTE) of the semiconductor chip 20 when it is formed of silicon is about 3.4 ppm/° C., and the coefficient of thermal expansion (CTE) of the first member 31 when it is formed of borosilicate glass is about 3.3 ppm/° C.

Further, it is desirable to set the coefficient of thermal expansion (CTE) of the second member 32 to be approximately equal to the coefficient of thermal expansion (CTE) of the semiconductor chip 20. This is because warpage or distortion of the completed semiconductor package 10 can be further reduced. Although silicon or borosilicate glass is suitable for the material of the second member 32, a metal having a coefficient of thermal expansion (CTE) close to that of silicon may be used. As an example of a metal usable as the material of the second member 32, there are the koval alloy (alloy of iron (54%), nickel (29%) and cobalt (17%): CTE=3.7 ppm/t), the 42-alloy (alloy of nickel (42%) and iron (58%): CTE=6.3 ppm/° C.), etc. Additionally, an effect of improving the thermal radiation performance of the semiconductor chip 20 can be obtained by using a metal as a material of the second member 32.

The resin part 39 is formed by filling a resin into a gap between each of the side surfaces of the semiconductor chip 20 and the respective inner side surfaces of the concave portion 30x. There may be a case where the resin part 39 is integrally formed with the first insulation layer 41 mentioned later depending on a manufacturing process of the semiconductor package 10 (refer to a second variation of the first embodiment mentioned later). An insulating resin such as, for example, an epoxy resin, a polyimide resin, etc., may be used as a material of the resin part 39. The width W2 of the resin part 39 can be set to, for example, about 500 μm.

The wiring structure 40 has a structure in which a first insulation layer 41, a first wiring layer 42, a second insulation layer 43, a second wiring layer 44, a third insulation layer 45, a third wiring layer 46, and a solder-resist layer 47 are laminated sequentially in that order. The thickness T3 of the wiring structure 40 can be set to, for example, about 30 μm to about 50 μm. Although the thickness (T1+T2) of the support member 30 and the thickness T3 of the wiring structure 40 are approximately the same in the drawing of FIG. 1, the thickness T3 of the wiring structure 40 is actually much smaller than the thickness (T1+T2) of the support member 30.

The first insulation layer 41 is formed on the primary surface 20a of the semiconductor chip 20 and the surface 30a of the support member 30 so as to cover the projection electrodes 23 of the semiconductor chip 20. As a material of the first insulation layer 41, an insulating resin such as an epoxy resin, a polyimide resin, etc., may be used. The thickness of the first insulation layer 41 can be set to about 10 μm.

The first wiring layer 42 is formed on the first insulation layer 41. The first wiring layer 42 includes via wirings and wiring patterns formed on the first insulation layer 41. The via wirings are filled in first via-holes 41x, which penetrate through the first insulation layer 41 and expose upper surfaces of the projection electrodes 23. The first wiring layer 42 is electrically connected to the projection electrodes 23 exposed on the bottom of the first via-holes 41x. As a material of the first wiring layer 42, for example, copper (Cu) or the like may be used. The thickness of the wiring patterns, which constitute the first wiring layer 42, can be set to, for example, about 5 μm.

The second insulation layer 43 is formed on the first insulation layer 41 to cover the first wiring layer 42. The material and thickness of the second insulation layer 43 can be the same as that of the first insulation layer 41.

The second wiring layer 44 is formed on the second insulation layer 43. The second wiring layer 44 includes via wirings and wiring patterns formed on the second insulation layer 43. The via wirings are filled in second via-holes 43x, which penetrate through the second insulation layer 43 and expose the upper surface of the first wiring layer 42. The second wiring layer 44 is electrically connected to the first wiring layer 42 exposed on the bottom of the second via-holes 43x. The material and thickness of the second wiring layer 44 can be the same as that of the first wiring layer 42.

The third insulation layer 45 is formed on the second insulation layer 43 so as to cover the second wiring layer 44. The material and thickness of the third insulation layer 45 can be the same as that of the first insulation layer 41.

The third wiring layer 46 is formed on the third insulation layer 45. The third wiring layer 46 includes via wirings and wiring patterns formed on the third insulation layer 45. The via wirings are filled in third via-holes 45x, which penetrate through the third insulation layer 45 and expose upper surface of the second wiring layer 44. The third wiring layer 46 is electrically connected to the second wiring layer 44 exposed on the bottom of the third via-holes 45x. The material and thickness of the third wiring layer 46 can be the same as that of the first wiring layer 42.

The solder-resist layer 47 is formed on the third insulation layer 45 so as to cover the third wiring layer 46. The solder-resist layer 47 has aperture parts 47x so that portions of the third wiring layer 46 are exposed on the bottoms of the aperture parts 47x of the solder-resist layer 47. As a material of the solder-resist layer 47, for example, a photosensitive resin such as an epoxy resin, acrylic resin, etc., may be used. The thickness of the solder-resist layer 47 can be set to, for example, about 20 μm.

If necessary, a metal layer may be formed on the third wiring layer 46 which is exposed on the bottoms of the aperture parts 47x. As an example of the metal layer, there are an Au layer, a Ni/Au layer (Ni layer and Au layer are laminated in that order), a Ni/Pd/Au layer (Ni layer, Pd layer and Au layer are laminated in that order), etc.

The external connection terminals 49 are formed on the third wiring layer 46 exposed on the bottoms of the aperture parts 47x. If the metal layer is formed on the third wiring layer 46, the external connection terminals 49 are formed on the metal layer. In the present embodiment, the semiconductor package 10 has a so-called fan-out structure in which an area where the external connection terminals 49 are formed is expanded to a periphery of an area directly above the semiconductor chip 20. That is, wiring patterns are extended so that the external connection terminals 49 are positioned above the surface 30a of the support member 30. The pitch of the adjacent external connection terminals 49 can be larger than the pitch of the adjacent projection electrodes 23 (for example, about 100 μm), and can be set to, for example, about 200 μm. However, the semiconductor package 10 may have a so-called fan-in structure depending on an application.

The external connection terminals 49 serve as terminals electrically connected to pads provided in a mounting board (not illustrated in the figure) such as a motherboard. For example, solder balls may be used as the external connection terminals 49. As a material of the solder balls, for example, an alloy containing Pb, an alloy of Sn and Cu, an alloy of Sn and Ag, an alloy of Sn, Ag and Cu, etc., may be used. Alternatively, lead pins may be used as the external connection terminals 49.

Although the external connection terminals 49 are formed in the present embodiment, the external connection terminals 49 are not necessarily formed. It is sufficient that portions of the third wiring layer are exposed from the solder-resist layer 47 so that the external connection terminals 49 can be provided when they are needed.

In the present embodiment, the width W1 of the surface 30a of the support member 30 is 200 μm to 500 μm. However, when realizing a semiconductor package having many terminals using a fan-out structure, the width W1 of the surface 30a of the support member 30 may be 0.5 mm to 6 mm, and a larger number of external connection terminals may be provided above the surface 30a of the support member 30.

Explained above is the structure of the semiconductor package 10 in which the wiring structure 40 is formed on the primary surface 20a of the semiconductor chip 20 and the surface 30a of the support member 30.

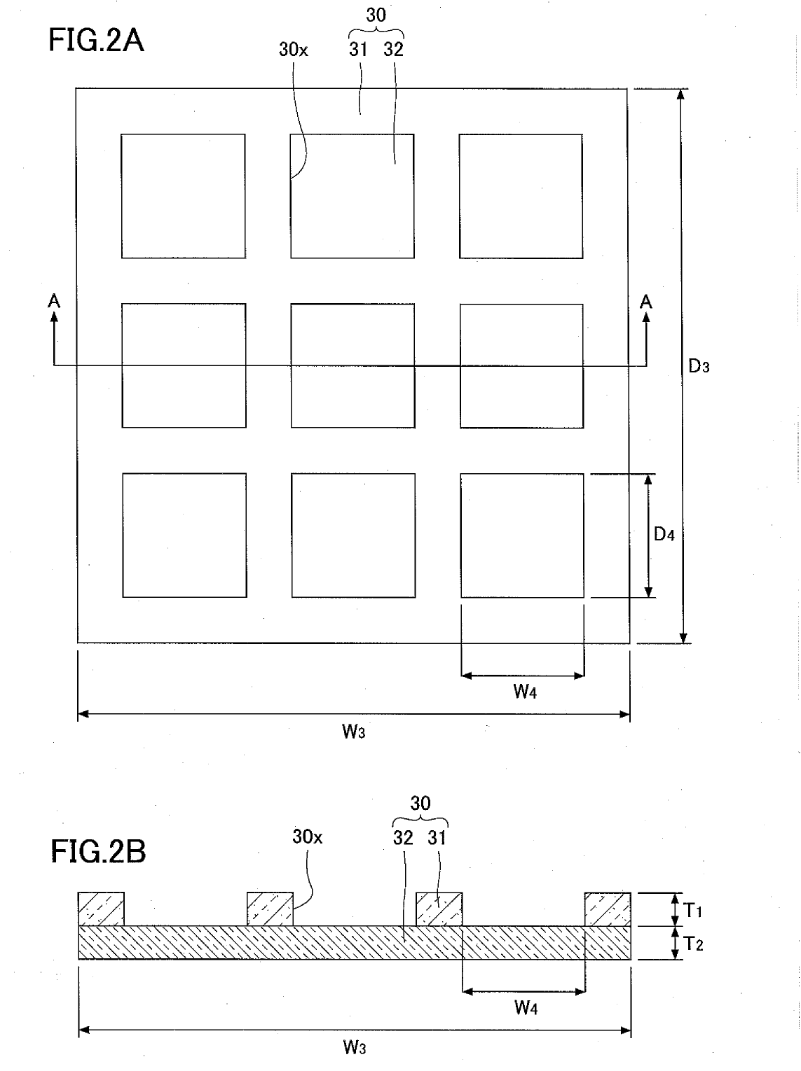

A description is given below of a manufacturing method of the semiconductor package according to the first embodiment. FIG. 2A through FIG. 12 are illustrations for explaining a manufacturing process of the semiconductor package according to the first embodiment.

First, the support member 30 having a plurality of the concave portions 30x on one surface thereof is formed as illustrated in FIGS. 2A and 2B. FIG. 2A is a plan view of the support member 30, and FIG. 2B is a cross-sectional view taken along a line A-A of FIG. 2A.

The support member 30 can be formed by joining the first member 31 and the second member 32 to each other by anodic bonding after polishing and planarizing the joining surfaces of the first and second members 31 and 32. If the surface 30a is also polished and planarized, it is effective for miniaturization of the wiring patterns. The first member 31 is formed of a flat plate material provided with a plurality of penetrating openings each having a generally rectangular planar shape, and the second member 32 is a flat plate member. The support member 30 is formed by joining the first member 31 to a surface of the second member 32 by anodic bonding so that the plurality of concave portions 30x are formed in the support member 30. Each of the concave portions 30x is defined by inner side surfaces of the penetrating opening having a generally rectangular planar shape formed in the first member and the surface of the second member 32 exposed in the penetrating opening. The penetrating openings of the first member 31 can be formed by an anisotropic etching method or the like. The materials of the first and second members 31 and 32 have been explained above.

The anodic bonding is a method of intimately joining the first member 31 and the second member 32 to each other by applying a high-temperature and a high-voltage. Specifically, for example, the first member 31 is placed on the surface of the second member 32, and the first member 31 and the second member 32 are heated (for example, 200° C. to 400° C.) while applying a high-voltage (for example, about 500 V to about 1000 V) by using one of the first member 31 and the second member 32 formed of borosilicate glass as a cathode and the other as an anode. Thereby, metal ions contained in the member using borosilicate glass are forcibly diffused toward the anode side and an electrostatic force is generated between the borosilicate glass and the other member to chemically join the first and second members 31 and 32 to each other.

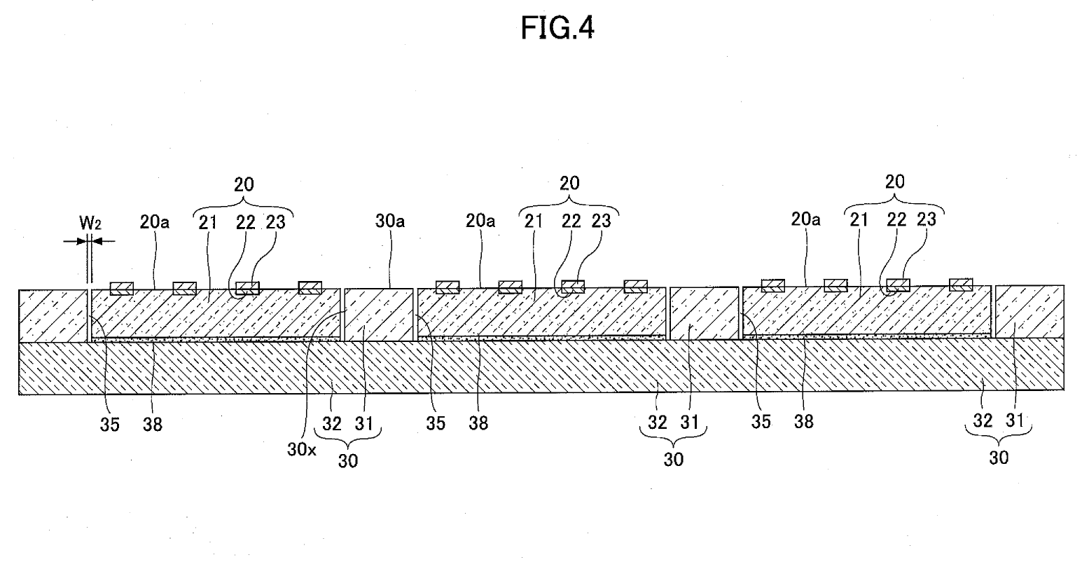

The width W3 and the depth D3 of the support member 30 can be set to, for example, about 200 mm, respectively. The thickness 11 of the first member 31 of the support member 30 (the depth of the concave portion 30x) can be set to, for example about 300 μm to about 500 μm. The thickness of the second member 32 can be set to, for example, about 300 μm to about 500 μm. The width W4 and the depth D4 of the concave portion 30x can be set to, for example, 15 mm, respectively. However, because the concave portion 30x is a portion in which the semiconductor chip 20 is accommodated in a process mentioned later (refer to FIG. 4), the width W4 and the depth D4 of the concave portion are determined so that the width W4 and the depth D4 become larger than the width and depth of the semiconductor chip 20, respectively. Additionally, the thickness T1 of the first member 31 (depth of the concave portion 30x) is determined so as to be approximately equal to the thickness of the semiconductor chip 20 with the double-sided adhesive 38 being applied to the back surface of the semiconductor chip 20.

Although the example where the planar shape of the support member 30 is a rectangular shape is explained in the present embodiment, the planar shape of the support member 30 may be a circular shape, an oval shape, etc. Additionally, although FIG. 2 illustrates nine pieces of the concave portions 30x each having the size of 15 mm×15 mm provided in the support member 30 having a size of 200 mm×200 mm for the purpose of simplification of the drawing, a larger number of concave portions 30x are actually formed in the support member 30.

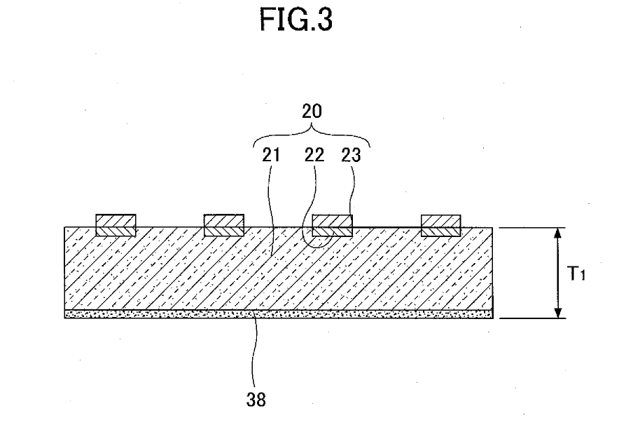

On the other hand, a predetermined number of semiconductor chips 20 are prepared separately from the preparation of the support member 30. As illustrated in FIG. 3, the semiconductor chip 20 includes the electrode pads 22 and the projection electrodes 23 formed on the primary surface. The double-sided adhesive 38 is applied to the back surface of the semiconductor chip 20. The semiconductor chip 20 having the double-sided adhesive 38 on the back surface thereof can be prepared by applying the double-sided adhesive 38 to an entire back surface of a wafer containing a plurality of semiconductor chips 20 and individualizing the semiconductor chips 20 by cutting the wafer together with the double-sided adhesive 38.

If it is necessary to make the semiconductor chip 20 thinner, the wafer may be thinned by grinding a back surface of the wafer using a backside grinder at a stage of wafer. Thereafter, the double-sided adhesive 38 is applied to the ground back surface of the wafer. The thickness T1 of the semiconductor chip 20 having the double-sided adhesive 38 can be set to, for example, about 300 μm to about 500 μm. The thickness of the double-sided adhesive 38 can be, for example, several tens μm.

Alternatively, the semiconductor chip 20 may be prepared without double-sided adhesive 38. In such a case, the double-sided adhesive 38 of a film form may be laminated on the bottom surface of each of the concave portions 30x of the support member 30 before the semiconductor chips 20 are accommodated in the concave portions 30 as illustrated in FIG. 4.

Then, the semiconductor chips 20, each of which has the double-sided adhesive 38 on the back surface thereof, are accommodated in the concave portions 30x of the support member 30, respectively, so that the primary surfaces 20a of the semiconductor chips 20 are exposed on the side of the surface 30a (in a face-up state). That is, the semiconductor chips 20 are accommodated in the concave portions 30x so that the projection electrodes 23 are exposed in opening parts of the concave portions 30x. The semiconductor chips 20 are fixed in the respective concave portions 30x by the double-sided adhesive 38. Alignment marks for positioning are formed previously on the support member 30 and the semiconductor chips 20. The alignment marks on the support member 30 and the semiconductor chips 20 are recognized using a positioning apparatus so as to position the semiconductor chips 20 relative to the support member 30, and accommodate the semiconductor chips 20 in the respective concave portions 30x of the support member 30.

As mentioned above, in order to accommodate the semiconductor chip 20, the width and the depth of the concave portion 30x is slightly larger than the width and the depth of the semiconductor chip 20. Thus, an air gap 35 is formed between each side surface of the semiconductor chip 20 and each inner surface of the concave portion 30x. The width W2 of the air gap 35 can be set to, for example, about 500 μm. In the present embodiment, the surface 30a of the support member 30 and the primary surface 20a of the semiconductor chip 20 are set substantially in the same plane.

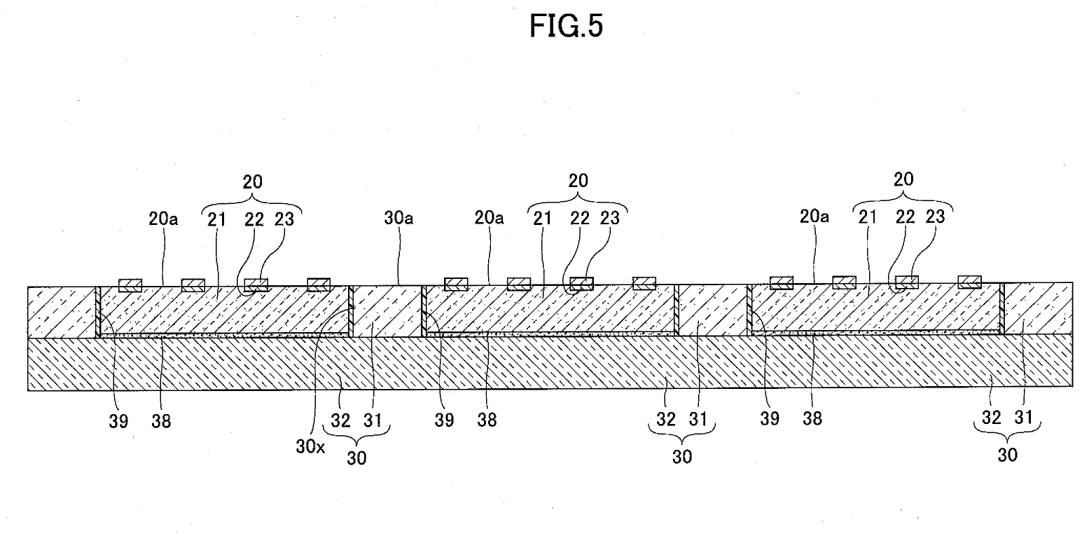

Next, as illustrated in FIG. 5, a resin is filled in the air gaps 35 using a dispenser or the like to form resin parts 39. As for the resin of the resin parts 39, for example, a thermosetting epoxy resin or polyimide resin in liquid form or paste form can be used. It is desirable for the resin parts 39 to use a resin material having excellent space-filling property. If a thermosetting epoxy resin or polyimide resin in liquid form or paste form is used, the resin is filled into the air gaps 35 and, thereafter, the filled resin is cured by heating at a temperature higher than the curing temperature to form the resin parts 39.

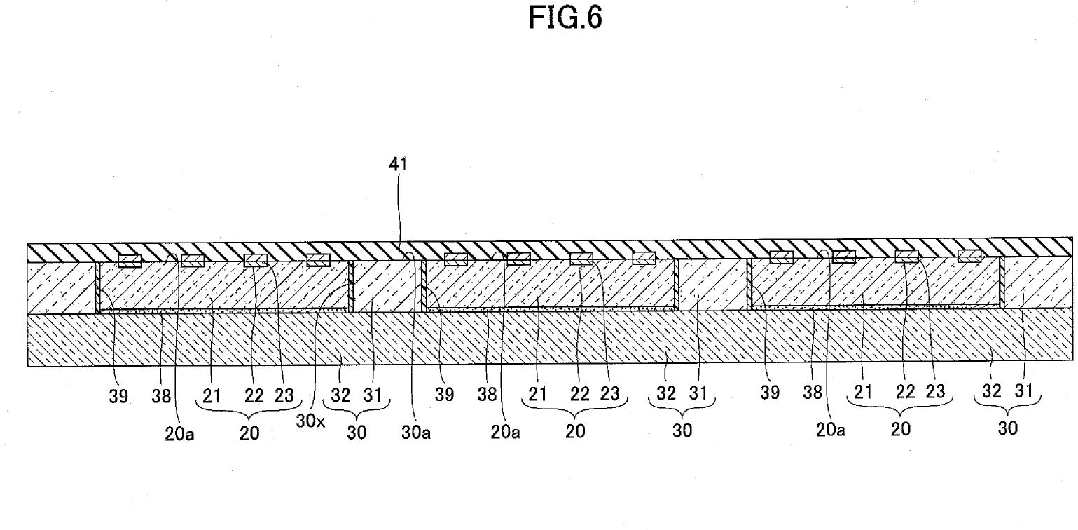

Then, as illustrated in FIG. 6, the first insulation layer 41 is formed on the primary surface 20a of each of the semiconductor chips 20 and the projection electrodes 23 provided on the side of the primary surface 20a of the each of the semiconductor chips 20. As the material to form the first insulation layer 41, a thermosetting epoxy resin or polyimide resin in a form of sheet, or a thermosetting epoxy resin or polyimide resin in liquid form or paste form can be used.

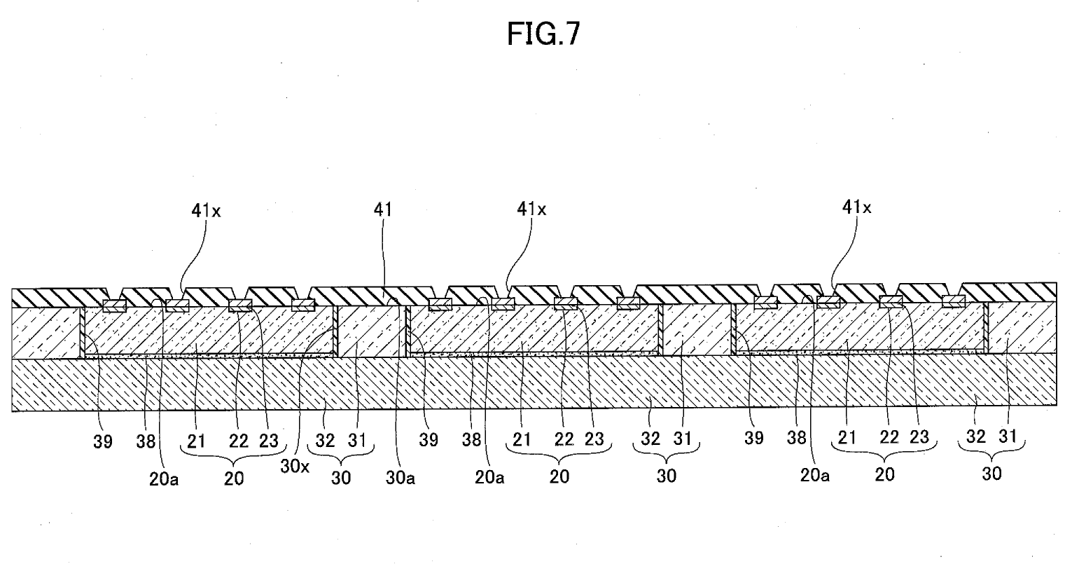

It is desirable for the first insulation layer 41 to use a resin material containing a filler such as, for example, silica (SiO₂) and having excellent machinability so that first via holes 41x can be formed easily by a laser machining method in the process mentioned below (refer to FIG. 7). By adjusting an amount of filler contained in the first insulation layer 41, the coefficient of thermal expansion of the first insulation layer 41 can also be adjusted. The same procedure may be applied to other insulating layers. The thickness of the first insulation layer 41 can be set to, for example, about 10 μm.

If a thermosetting epoxy resin or polyimide resin in a form of sheet is used as the material of the first insulation layer 41, the first insulation layer 41, which is in a form of sheet and in a semi-cured state, is laminated onto the primary surfaces 20a of the semiconductor ships 20 and the surface 30a of the support member 30 to cover the projection electrodes 23 of the semiconductor chips 20. Then, the laminated first insulation layer 41 is cured by heating at a temperature higher than the thermosetting temperature while pressing the first insulation layer 41. The first insulation layer 41 is prevented from forming voids therein by laminating the first insulation layer 41 in a vacuum atmosphere.

If a thermosetting epoxy resin or polyimide resin in liquid form or paste form is used as the material of the first insulation layer 41, the first insulation layer 41 in a form of liquid or paste is applied onto the primary surfaces 20a of the semiconductor ships 20 and the surface 30a of the support member 30 by, for example, a spin-coat method to cover the projection electrodes 23 of the semiconductor chips 20. Then, the applied first insulation layer 41 is cured by heating at a temperature higher than the thermosetting temperature.

Next, as illustrated in FIG. 7, the first via holes 41x, which penetrate the first insulation layer 41 and expose top surfaces of the projection electrodes 23, are formed in the first insulation layer 41. The first via holes 41x can be formed by, for example, a laser processing method using a CO₂ laser. Each of the first via holes 41 formed by a laser processing method forms a concave portion having a conical shape having a bottom surface defined by the top surface of each of the projection electrodes 23. A top end of each of the first via holes 41x opens on the side where the second insulation layer 43 is formed. It should be noted that other via holes may have the same conical shape if they are formed by a laser processing method. If the first via holes 41x are formed by a laser processing method, it is desirable to apply a desmear process to remove residue of the resin forming the first insulation layer 41, which adheres to the top surfaces of the projection electrodes 23 exposed on the bottoms of the first via holes 41x. The same applies to other via holes if they are formed by a laser processing method.

The first via holes 41x may be formed by patterning the first insulation layer 41, which is formed of a photosensitive resin, by a photography method. Alternatively, the first via holes 41x may be formed by printing a resin paste through a screen mask, which masks positions corresponding to the first via holes 41, and curing the resin paste.

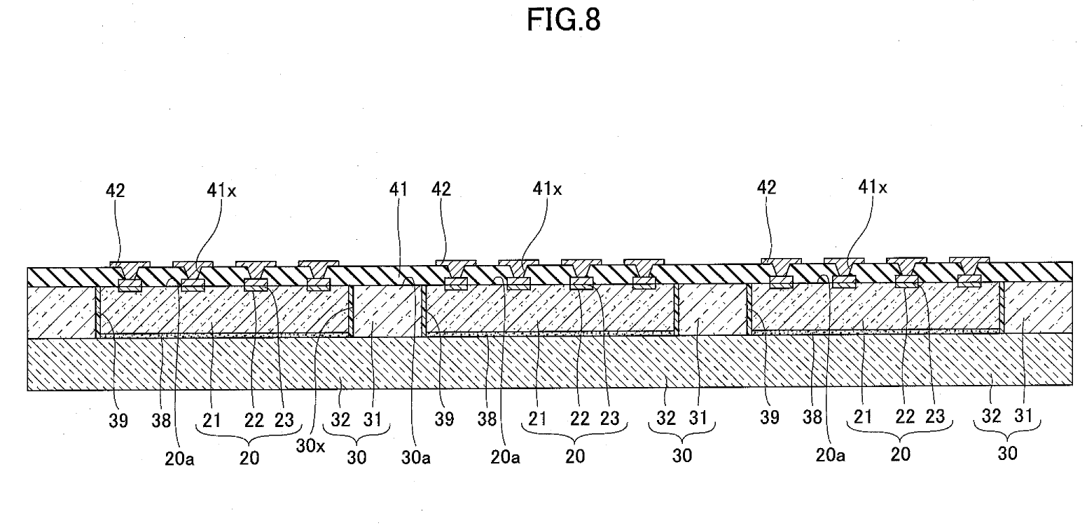

Next, as illustrated in FIG. 8, the first wiring layer 42 is formed on the first insulation layer 41. The first wiring layer 42 includes via wirings filled in the first via holes 41x and wiring patterns formed on the first insulation layer 41. The first wiring layer 42 is electrically connected directly to the projection electrodes 23 exposed on the bottoms of the first via-holes 41x. As a material of the first wiring layer 42, for example, copper (Cu) or the like can be used. The first wiring layer 42 can be formed using various kinds of wiring-forming methods, such as a semi-additive method and a subtractive method. As an example, a process of forming the first wiring layer 42 using a semi-additive method is described below.

First, a seed layer (not illustrated in the figure) made of copper (Cu) or the like is formed on the top surfaces of the projection electrodes 23 exposed on the bottoms of the first via holes 41x and the surface of the first insulation layer 41 including inner surfaces of the first via holes 41x. Further, a resist layer (not illustrated in the figure) is formed on the seed layer. Then, openings corresponding to the first wiring layer 42 are formed by exposing and developing the resist layer formed on the seed layer.

Then, a wiring layer, which is made of copper (Cu) or the like, is formed in the openings of the resist layer by an electrolytic plating method using the seed layer as an electricity-supplying layer. Subsequently, the resist layer is removed, and, thereafter, portions of the seed layer, which are not covered by the wiring layer, are removed by etching. Thereby, the first wiring layer 42 is formed on the first insulation layer 41.

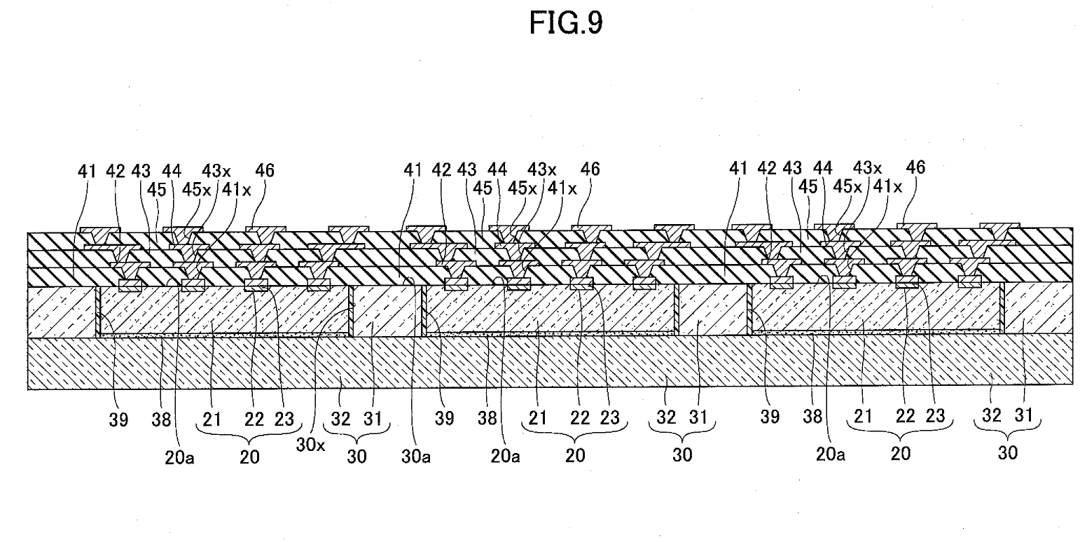

Next, as illustrated in FIG. 9, the second insulation layer 43, the second wiring layer 44, the third insulation layer 45, and the third wiring layer 46 are laminated by repeating a process the same as the process explained with reference to FIGS. 6 through 8. That is, after forming the second insulation layer 43, which covers the first wiring layer 42, second via holes 43x are formed in the second insulation layer 43 on the first wiring layer 42.

Further, the second wiring layer 44, which is connected to the first wiring layer 42 through the second via holes 43x, is formed on the second insulation layer 43. As a material to form the second wiring layer 44, for example, copper (Cu) or the like can be used. The second wiring layer 44 is formed by, for example, a semi-additive method.

Further, after forming the third insulation layer 45 to cover the second wiring layer 44, third via holes 45x are formed in the third insulation layer 45 on the second wiring layer 44. Then, the third wiring layer 46, which is connected to the second wiring layer 44 through the third via holes 45x, is formed on the third insulation layer 45. As a material to form the third wiring layer 45, for example, copper (Cu) or the like can be used. The third wiring layer 46 is formed by, for example, a semi-additive method.

The three build-up wiring layers (first wiring layer 42, the second wiring layer 44, and the third wiring layer 46) are formed on the primary surfaces 20a of the semiconductor chips 20 and the surface 30a of the support member 30 by the process explained with reference to FIGS. 6 through 9. The number of the build-up wiring layers may be one layer or two layers, and more than three build-up wiring layers may be formed by repeating the process explained with reference to FIGS. 6 through 8 after the process explained with reference to FIG. 9.

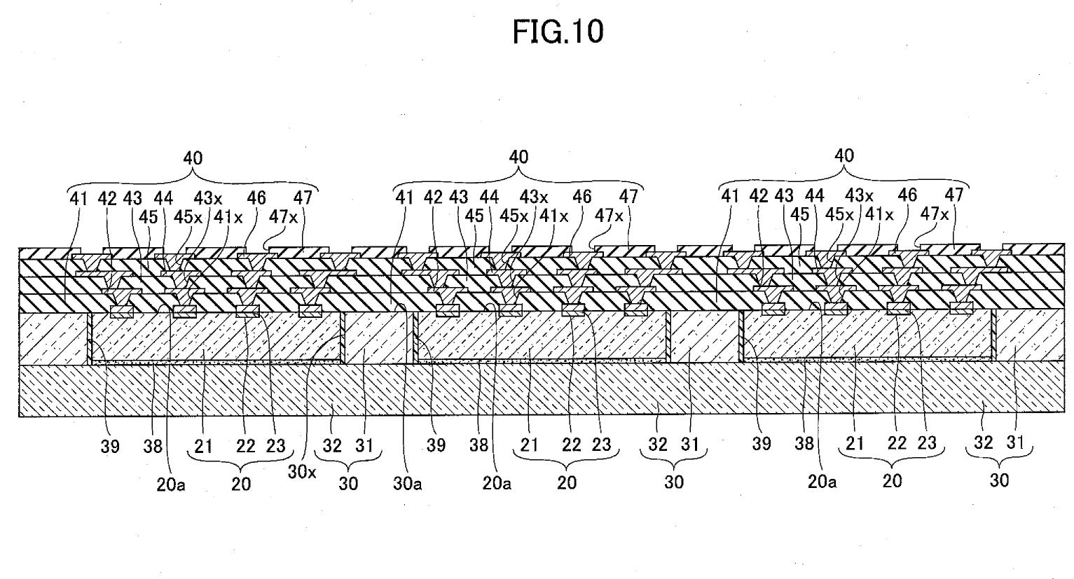

Next, as illustrated in FIG. 10, the solder resist layer 47 having openings 47x is formed on the third insulation layer 45 to cover the third wiring layer 46. Specifically, a solder resist made of a photosensitive resin containing, for example, an epoxy resin, an acrylic resin, etc., is applied to the third insulation layer 45 to cover the third wiring layer 46. Then, the applied solder resist is exposed and developed to form the openings 47x. Thereby, the solder resist layer 47 having the openings 47x is formed. Portions of the third wiring layer 46 are exposed on the bottoms of the openings 47x of the solder resist layer 47.

If necessary, a metal layer may be formed on the third wiring layer 46 exposed on the bottoms of the openings 47x. As examples of the metal layer, there are an Au layer, a Ni/Au layer (a metal layer of Ni layer and Au layer stacked in that order), and a Ni/Pd/Au layer (a metal layer of Ni layer, Pd layer and Au layer stacked in that order). The metal layer can be formed by, for example, an electroless plating method.

As mentioned above, the wiring structure 40 including wiring layers electrically connected to the semiconductor chips 20 is formed on the primary surfaces 20a of the semiconductor chips 20 and the surface 30a of the support member 30 by the process explained with reference to FIGS. 6 through 10.

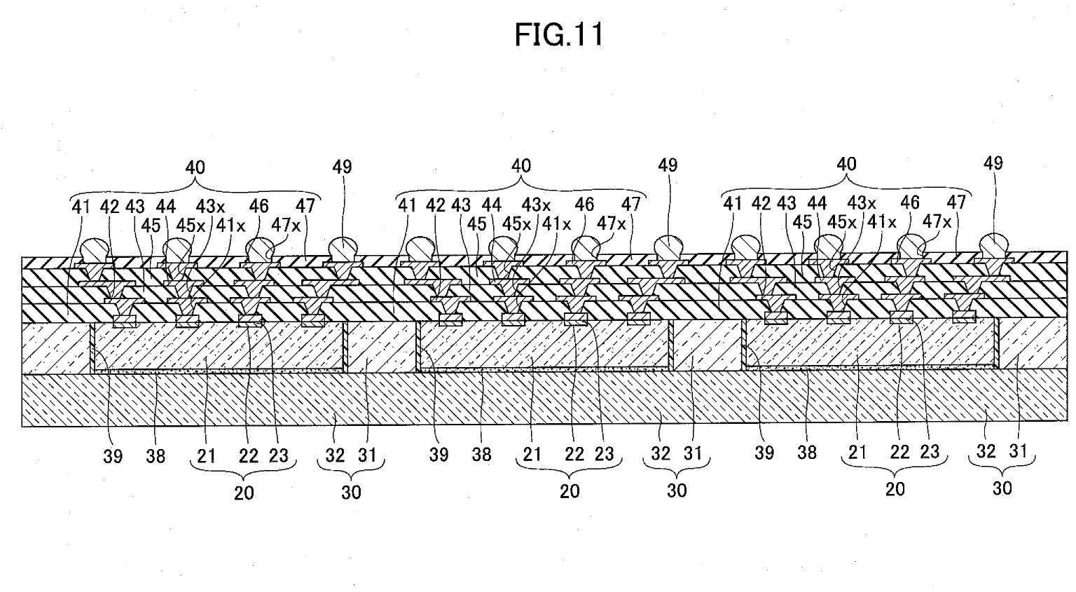

Next, as illustrated in FIG. 11, the external connection terminals 49 are formed on the third wiring layer 46 exposed on the bottoms of the openings 47x. If a metal layer is formed on the third wiring layer 46, the external connection terminals 49 are formed on the metal layer. In the present embodiment, the semiconductor package 10 has a so-called fan-out structure in which an area where the external connection terminals 49 are formed extends to a periphery of an area directly above the semiconductor chip 20. However, the semiconductor package 10 may have a so-called fan-in structure depending on an application.

The external connection terminals 49 serve as terminals electrically connected to pads provided on a mounting board (not illustrated in the figure) such as a motherboard. As a material to form the external connection terminal 49, for example, a solder ball or the like can be used. As a material of the solder ball, for example, an alloy containing Pb, an alloy of Sn and Cu, an alloy of Sn and Ag, an alloy of Sn, Ag and Cu, etc., may be used.

The external connection terminals 49 can be formed by applying a flux as a surface treatment agent on the third wiring layer 46, placing solder balls and reflowing the solder balls at a temperature ranging from about 240° C. to about 260° C., and, then, removing the flux by cleaning the surface. If a metal layer is formed on the third wiring layer 46, the flux may be applied onto the metal layer. However, lead pins may be used for the external connection terminals instead of solder balls.

Although the external connection terminals 49 are formed in the present embodiment, it is not always necessary to form the external connection terminals 49. What is necessary is that portions of the third wiring layer 46 are exposed in the openings 47x of the solder resist layer 47 so that the external connection terminals can be formed if it is necessary.

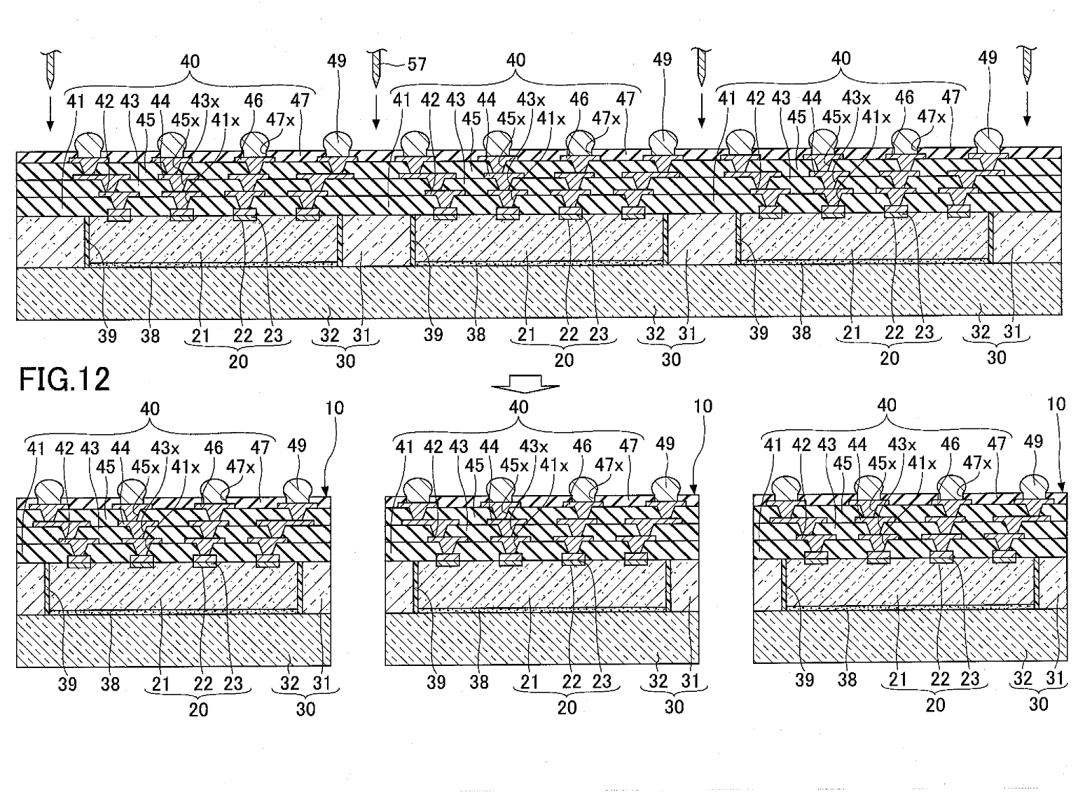

Next, as illustrated in FIG. 12, the structure illustrated in FIG. 11 is cut along predetermined lines to divide the support member 30 and the wiring structure 40, thereby individualizing each semiconductor package 10. The cutting of the structure illustrated in FIG. 12 can be done by dicing using a dicing blade 57 or the like. The individualization can be achieved by cutting portions of the support member 30 and the wiring structure 40 between the adjacent semiconductor chips 20. However cutting may be performed so that each cut-out portion contains a plurality of semiconductor chips 20.

According to the above-mentioned first embodiment, silicon or borosilicate glass is used as the material of the first member 31, and silicon, borosilicate glass or metal is used as the material of the second member 32, wherein one of the first member 32 and the second member 32 is made of borosilicate. Then, the first member 31 and the second member 32 are joined to each other by anodic bonding to form the support member 30 having the surface 30a on which concave portions 30x are formed. The semiconductor chips 20 are accommodated in the concave portions 30x, and the wiring structures 40 are formed on the primary surfaces 20 of the semiconductor chips 20 and the surface 30a of the support member 30.

Consequently, there is no problem of unevenness in a gold plating layer or an adhesive layer occurs, which problem may occur when the first member and the second member are joined to each other via the gold plating layer or the adhesive layer. Accordingly, an inclination of the surface 30a of the support member 30 relative to the primary surfaces 20a of the semiconductor chips 20 can be reduced. Thereby, accuracy in the exposure and development performed in the process of forming the wiring patterns can be improved, which enables miniaturization of wiring patterns formed on the primary surfaces 20a of the semiconductor chips 20 and the surface 30a of the support member 30. Additionally, silicon or borosilicate used as the material of the first member 31 has a surface smoother than a surface of metal, which contributes to the miniaturization and densification of the wiring patterns formed on the primary surfaces 20a of the semiconductor chips 20 and the surface 30a of the support member 30.

Moreover, by using silicon or borosilicate glass as a material of the first member, it becomes possible to make the coefficient of thermal expansion (CTE) of the first member of the same level as the coefficient of thermal expansion (CTE) of the semiconductor chip, thereby suppressing warpage or distortion in the completed semiconductor package.

Furthermore, it becomes possible to make the coefficient of thermal expansion (CTE) of the second member of the same level as the coefficient of thermal expansion (CTE) of the semiconductor chip and the first member, thereby suppressing warpage or distortion in the completed semiconductor package. Although silicon and borosilicate glass are suitable for the material of the second member, the Koval or the 42-alloy, which has a coefficient of thermal expansion (CTE) close to that of silicon may be used. Additionally, the heat-release performance of the semiconductor chip can be improved by using a metal as the material of the second member of the support member.

<First Variation of First Embodiment>

In the first embodiment, the support member 30 is formed by joining the first member 31 and the second member 32 to each other by anodic bonding. On the other hand, in a first variation of the first embodiment, the support member 30 is formed by joining the first member 31 and the second member 32 to each other by plasma bonding.

That is, when forming the support member 30 by joining the first member 31 and the second member 32 to each other, plasma bonding is used instead of anodic bonding. The plasma bonding used in the first variation of the first embodiment refers to any methods including exposing joining surfaces of the first and second members 31 and 32 to a plasma (for example Ar plasma), after planarizing the joining surfaces by polishing, to remove oxidation films or contaminants from the joining surfaces, and contacting the joining surfaces to each other without any oxidation films therebetween to bond the joining surfaces based on an interatomic force of attraction. That is, the plasma bonding referred to in the first variation of the first embodiment includes a plasma activation low-temperature bonding, a plasma low-temperature bonding, a surface activation bonding according to plasma irradiation, a normal-temperature bonding according to plasma irradiation, etc.

When joining the first member 31 and the second member 32 to each other by plasma bonding, silicon or borosilicate glass can be used as the material of the first member 31. Silicon, borosilicate glass or metal can be used as the material of the second member 32. Unlike the case of joining the first member 31 and the second member 32 by anodic bonding, it is not necessary to meet a requirement that one of the first member 31 and the second member 32 must be made of borosilicate glass. Accordingly, the aforementioned materials may be combined arbitrarily, and the same materials can be joined by plasma bonding.

According to the first variation of the first embodiment, the same effects as the first embodiment can be obtained even if the first member and the second member are joined by plasma bonding, and further the following effect can be obtained. That is, the first member and the second member can be joined to each other when both of the first and second members are made of borosilicate glass, or when neither of the first and second members is made of borosilicate glass, thereby improving a freedom in selecting materials for the first and second member.

As mentioned above, according to the first variation of the first embodiment, the same effects as the above-mentioned first embodiment can be obtained by directly joining the first member and the second member to each other using a method such as anodic bonding, plasma bonding or the like without providing a gold plated layer or an adhesive layer between the first member and the second member

<Second Variation of First Embodiment>

In the first embodiment, as illustrated in FIG. 5, the resin parts 39 are formed by filling a resin in the air gaps 35 illustrated in FIG. 4. In a second variation of the first embodiment, the process of filling a resin in the air gaps 35 as illustrated in FIG. 5 is omitted. In the description of the second variation of the first embodiment, explanations of parts that are the same as the parts already explained are omitted.

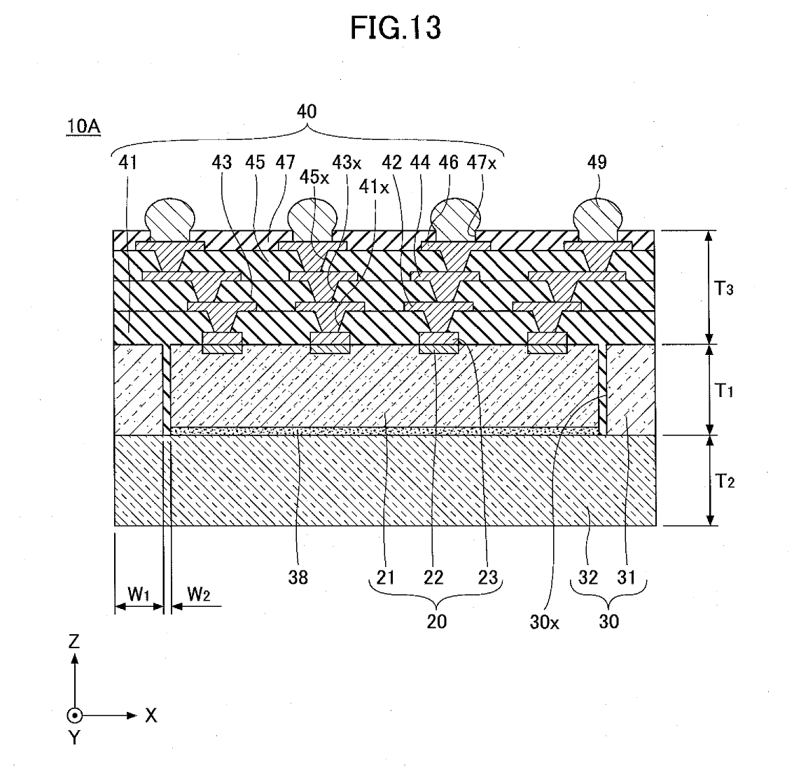

FIG. 13 is a cross-sectional view of a semiconductor package according to the second variation of the first embodiment. Referring to FIG. 13, the semiconductor package 10A differs from the semiconductor package 10 (refer to FIG. 1) in that the first insulation layer 41, instead of the resin parts 39, is filled into the gap between each of the side surfaces of the semiconductor chip 20 and each of the inner side surfaces of the concave portion 30x.

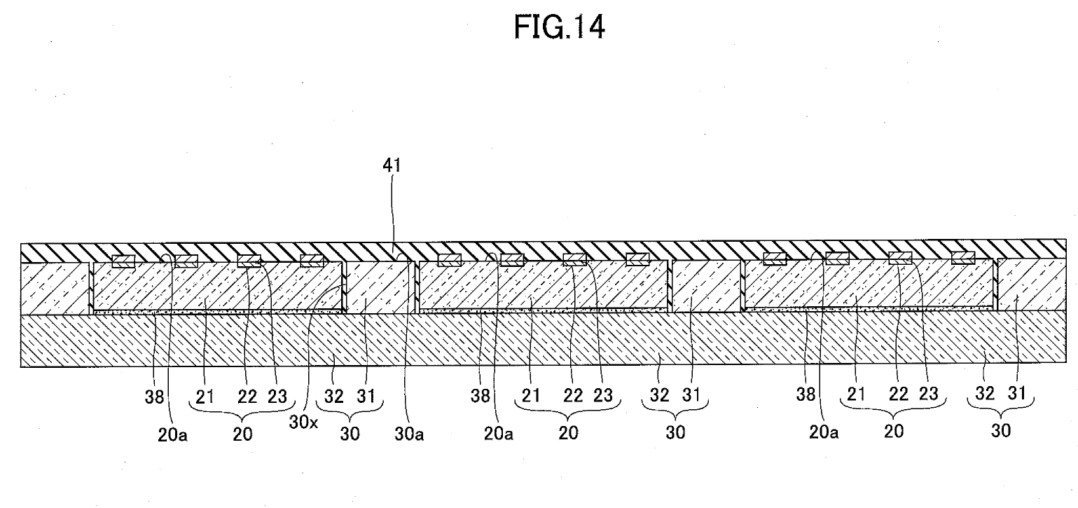

First, in order to manufacture semiconductor package 10A, the process of the first embodiment explained with reference to FIGS. 2 through 4 is performed. Then, as illustrated in FIG. 14, the first insulation layer 41 is filled in the gaps between the semiconductor chip 20 and the inner surfaces of the concave portion 30x. In order to fill the first insulation layer in the gaps, a thermosetting epoxy resin or polyimide resin in liquid form or paste form is used as the material of the first insulation layer 41. The thermosetting epoxy resin or polyimide resin in liquid form or paste form is applied by, for example, a spin-coat method so as to cover the projection electrodes 23 of the semiconductor chip 20. The liquid or paste material of the first insulation layer 41 is filled into the air gaps 35 illustrated in FIG. 4. Then, the material of the first insulation layer 41, which has been applied to the primary surfaces 20a of the semiconductor chips 20 and the surface 30a of the support member 30 and also filled into the air gaps 35, is heated at a temperature higher than the curing temperature and cured.

Thereby, the resin of the first insulation layer 41 is filled into the air gaps 35 and the first insulation layer is formed on the primary surfaces 20a of the semiconductor chips 20 and the surface 30a of the support member 30 to cover the projection electrodes 20 of the semiconductor chips 20 in a single process. As a result, the manufacturing process of the semiconductor package 10A is simplified, which provides an effect of reducing the manufacturing cost of the semiconductor package 10A.

Next, by performing the process of the first embodiment explained with reference to FIG. 7 through 12, the semiconductor package 10A illustrated in FIG. 13 is completed. If a photosensitive resin in liquid form or paste form is used as the material of the first insulation layer 41 in the process explained with reference to FIG. 14, the first via holes 41x can be formed by patterning the first insulation layer 41 using a photolithography method in the process explained with reference to FIG. 7.

Thus, according to the second variation of the first embodiment, the same effect as the first embodiment can be obtained, and further the following effect can also be obtained. That is, by using an epoxy resin or polyimide resin in liquid form or paste form as the material of the first insulation layer, the resin of the material of the first insulation layer is filled into the air gaps and also the first insulation layer can be formed on the primary surfaces of the semiconductor chips and the surface of the support member to cover the projection electrodes of the semiconductor chips in a single process. As a result, the manufacturing process of the semiconductor package can be simplified, which reduces the manufacturing cost of the semiconductor package.

<Third Variation of First Embodiment>

In the first embodiment, as illustrated in FIG. 5, the resin parts 39 are formed by filling a resin into the entire portion of each of the air gaps 35 illustrated in FIG. 4. That is, the resin is filled so that top surfaces of the resin parts 39 lie substantially in the same plane of the primary surfaces 20a of the semiconductor chips 20. According to the third variation of the first embodiment, a resin forming the resin parts 39 is filled into portions of the air gaps 35. In the description of the third variation of the first embodiment, explanations of parts that are the same as parts already explained in the first embodiment are omitted.

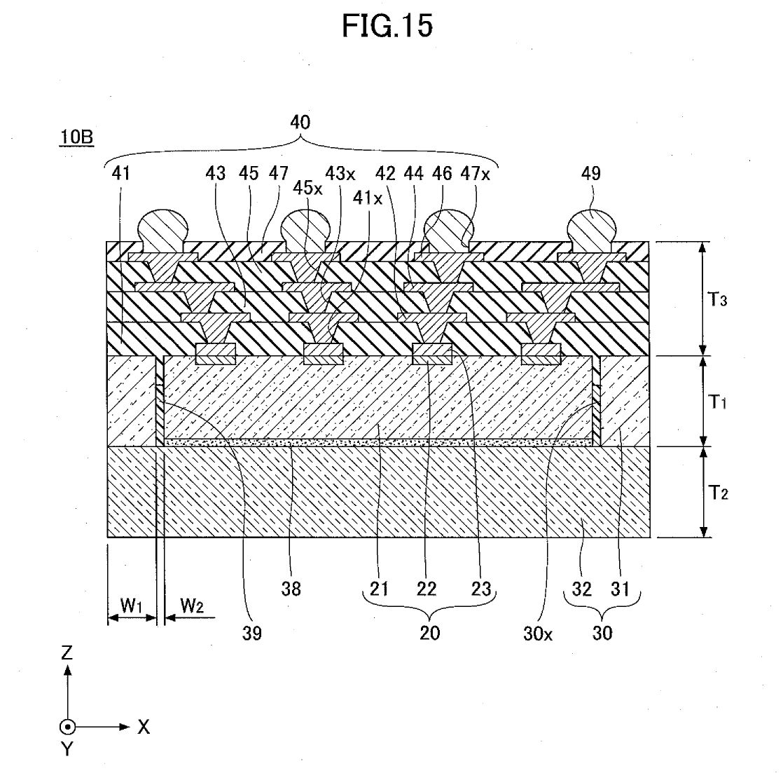

FIG. 15 is a cross-sectional view of a semiconductor package according to the third variation of the first embodiment. Referring to FIG. 15, the semiconductor package 10B differs from the semiconductor package 10 (refer to FIG. 1) in that the resin forming the resin part 39 is filled into a portion of each air gap between the side surface of the semiconductor chip 20 and the inner surface of the concave portion 30x and the first insulation layer 41 is filled into the remaining portion of the air gap.

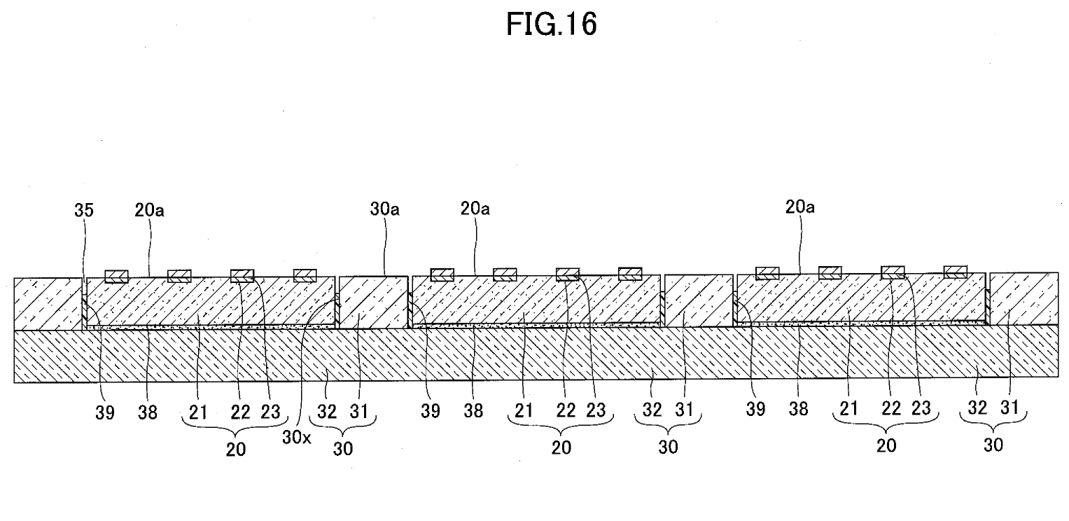

First, in order to manufacture the semiconductor package 10B, the process of the first embodiment explained with reference to FIGS. 2 through 4 is performed. Then, as illustrated in FIG. 16, a resin is filled into a portion of each of the air gaps 35 to form the resin parts 39. As the material of the resin parts 39, for example, a thermosetting epoxy resin or polyamide resin in liquid form or paste form can be used. It is desirable to form the resin parts 39 by a material having excellent space-filling property. If a thermosetting epoxy resin or polyamide resin in liquid form or paste form is used as the material of the resin parts 39, the resin parts 39 is heated and cured at a temperature higher than the curing temperature after the resin is filled into the portion of each of the air gaps 35.

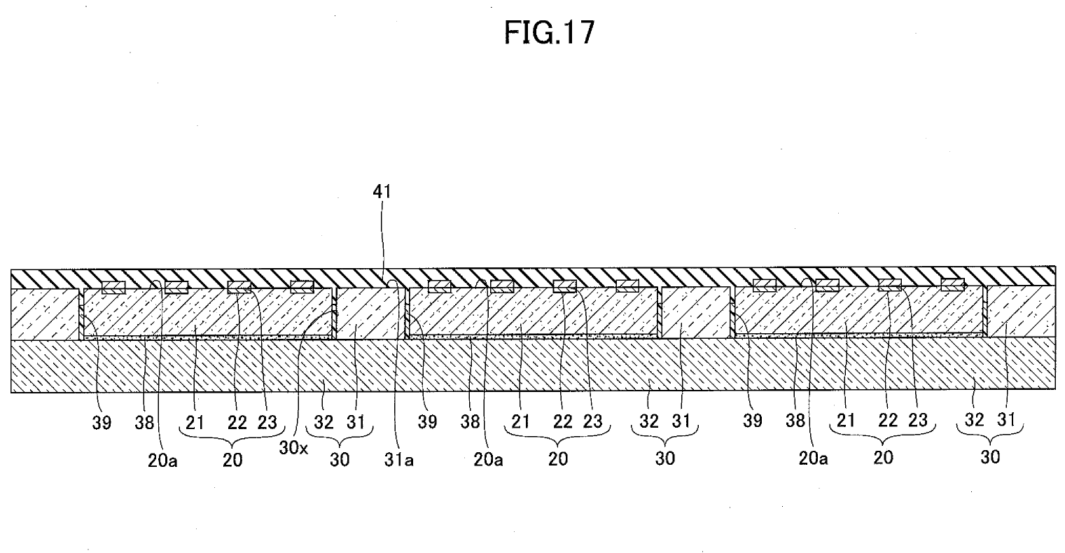

Next, as illustrated in FIG. 17, a thermosetting epoxy resin or polyimide resin in liquid form or paste form, which is a material to form the first insulation layer 41, is applied to the primary surfaces 20a of the semiconductor chips 20 and the surface 30a of the support member 30 by, for example, a spin coat method so as to cover the projection electrodes 23 of the semiconductor chips 20. The liquid or paste material of the first insulation layer 41 is filled into a portion of each of the air gaps 35 above the resin part 39. Then, the material of the first insulation layer 41, which has been applied to the primary surfaces 20a of the semiconductor chips 20 and the surface 30a of the support member 30 and also filled into the upper portion of each of the air gaps 35 above the resin part 39, is heated and cured at a temperature higher than the curing temperature.

Then, the process of the first embodiment explained with reference to FIGS. 7 through 12 is performed to complete the semiconductor package 10B illustrated in FIG. 15. If a liquid or paste of a photosensitive resin is used as a material of the first insulation layer 41 in the process explained with reference to FIG. 17, the first via holes 41x can be formed by patterning the first insulation layer 41 using a photolithography method in the process explained with reference to FIG. 7.

As mentioned above, according to the third variation of the first embodiment, the same effect as the first embodiment can be obtained, and further the following effect can also be obtained. That is, by filling a resin into only a portion of each of the air gaps, the resin is prevented from being run over on the primary surfaces of the semiconductor chips or the surface of the support member.

### Second Embodiment

In the first embodiment, the support member 30 includes the first member 31 and the second member 32. In a second embodiment, a support member formed of a single material is used. In the second embodiment, explanations of parts that are the same as parts already explained in the first embodiment and variations thereof are omitted.

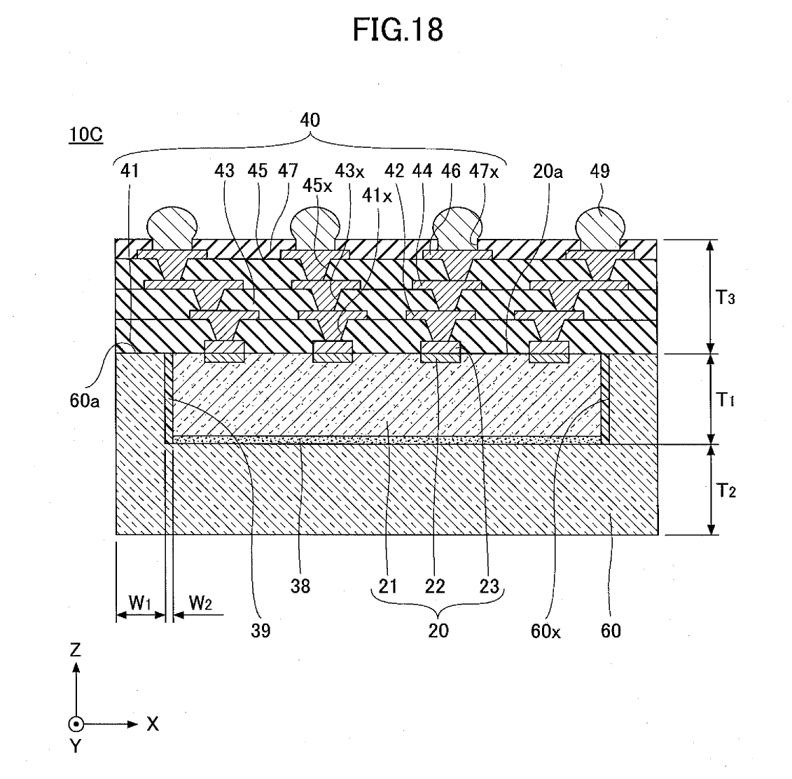

FIG. 18 is a cross-sectional view of a semiconductor package according to the second embodiment. Referring to FIG. 18, the semiconductor package 10C differs from the semiconductor package (refer to FIG. 1) in that a support member 60 is used instead of the support member 30.

The support member 60 is made of a single material, and a concave portion 60x is formed in one surface 60a of the support member 60. The surface 60a lies substantially in the same plane as the primary surface 20a of the semiconductor chip 20. The depth T1 of the concave portion 60 can be set to, for example, about 300 μm to about 500 μm. The depth T1 of the concave portion 60 is approximately equal to a sum of the thickness of the semiconductor chip 20 and the thickness of the double-sided adhesive 38. The thickness T2 of a portion of the support member 60 on the backside of the semiconductor chip 20 can be set to, for example, about 300 μm to about 500 μm. The width W1 of the surface 60a of the support member 60 on the side of the side surface of the semiconductor chip 20 can be set to, for example, about 200 μm to about 500 μm. As a material to form the support member 60, silicon or borosilicate glass is used.

Thus, the surface 60a of the support member 60 can be made smoother than a surface of a metal by using silicon or borosilicate glass as the material of the support member 60. Therefore, the wiring patterns formed on the primary surface 20a of the semiconductor chip 20 and the surface 60a of the support member 60 can be miniaturized.

Moreover, by using silicon or borosilicate glass as the material of the support member 60, it becomes possible to make the coefficient of thermal expansion (CTE) of the support member 60 of the same level as the coefficient of thermal expansion (CTE) of the semiconductor chip 20, thereby suppressing warpage or distortion in the completed semiconductor package 10C.

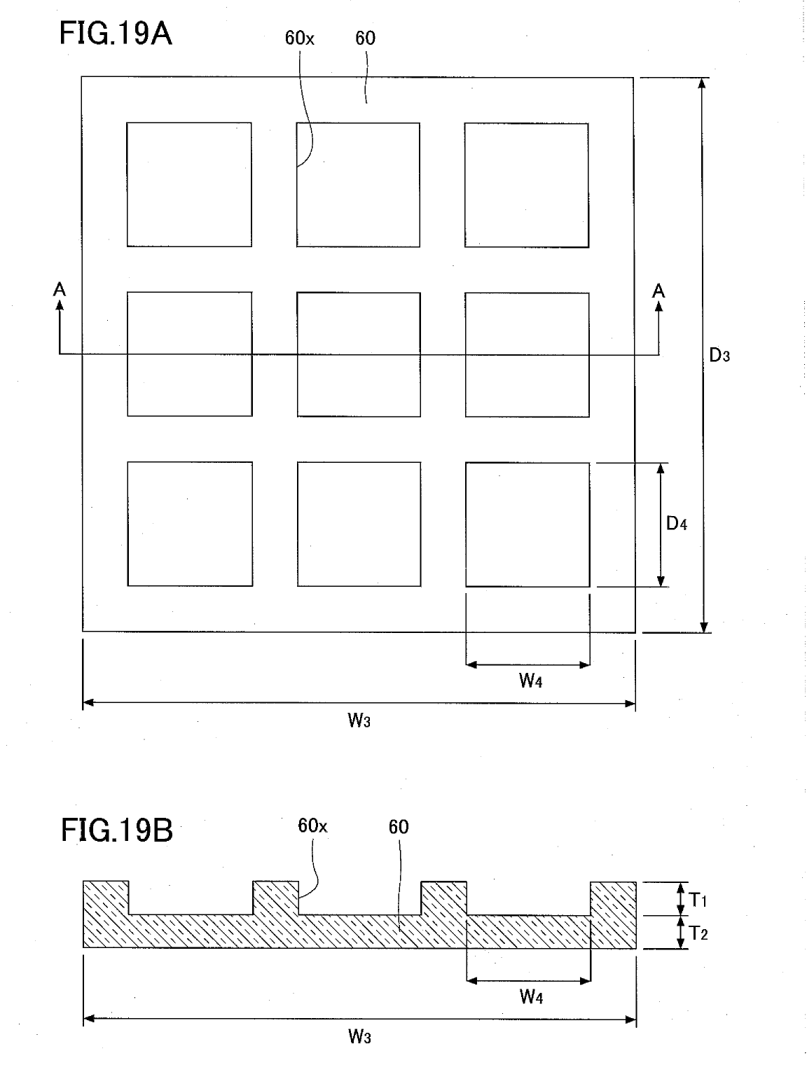

First, in order to manufacture the semiconductor package 10C, the support member 60 having concave portions 60x is fabricated as illustrated in FIGS. 19A and 19B. The concave portions 60x can be formed by forming a resist layer on the support member 60 to expose only areas corresponding to the concave portions 60x and etching the support member 60 by using the resist layer as a mask. It is desirable to use an anisotropic etching method such as a deep reactive ion etching (DRIE) or the like to form the concave portions 60x. Thereafter, the process of the first embodiment explained with reference to FIGS. 3 through 12 is performed to complete the semiconductor package 10C illustrated in FIG. 18.

As mentioned above, according to the second embodiment, the same effect as the first embodiment can be obtained even if the support member is made of a single material of silicon or borosilicate glass and the concave portion is formed by etching.

### Third Embodiment

A description is given below of a third embodiment. In the third embodiment, a support member having a concave portion of which inner side surfaces are tapered is used. In the third embodiment, descriptions of parts that are the same as the parts already explained in the above mentioned embodiments and their variations are omitted.

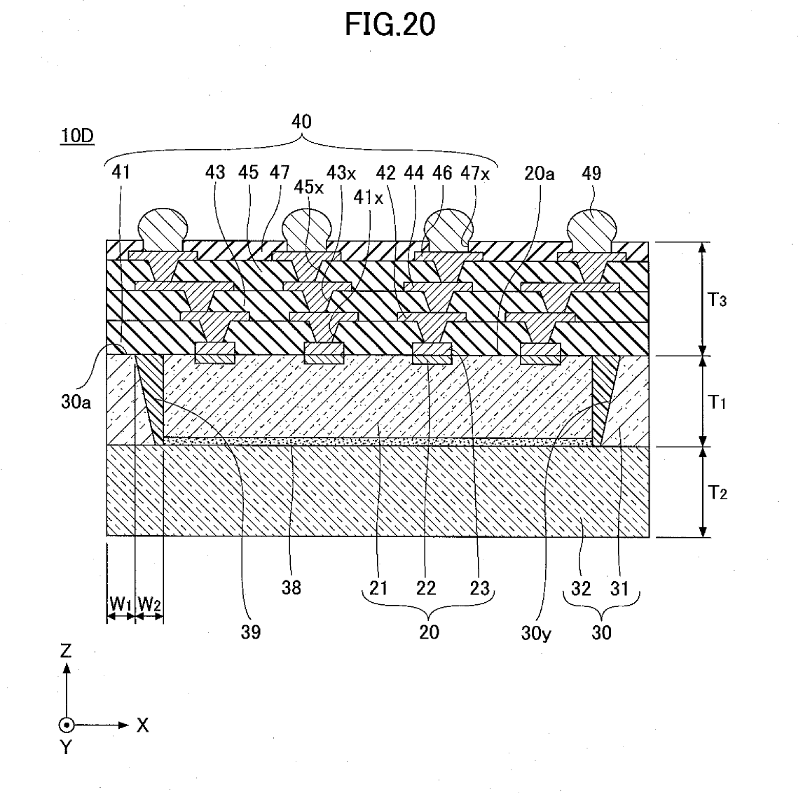

FIG. 20 is a cross-sectional view of a semiconductor package according to the third embodiment. Referring to FIG. 20, the semiconductor package 100 differs from the semiconductor package (refer to FIG. 1) in that the concave portion 30x of the semiconductor package 10 is replaced by a concave portion 30y.

The concave portion 30y is formed in the surface 30a of the support member 30. More specifically, the support member 30 has the first member 31 and the second member 32, and the first member 31 is joined to the surface of the flat shaped second member 32 by anodic bonding. A penetrating opening of a generally rectangular planar shape is provided in the first member 31. The concave portion 30y is formed by inner surfaces of the penetrating opening and the surface of the second member 32 exposed in the penetrating opening. The semiconductor chip 20 is accommodated in the concave portion 30y.

The inner surfaces of the penetrating opening formed in the first member 31 is tapered so that an area of the open side (the side of the first insulation layer 41) is larger than an area of the bottom side (the side of the second member 32). That is, the concave portion 30y has a bottom surface and tapered inner surfaces slanted relative to the bottom surface. The bottom surface is defined by the surface of the second member 32 and has a substantially rectangular planar shape. The inner surfaces are tapered so that a horizontal cross section of the concave portion 30y is gradually enlarged toward the open side of the concave portion 30y.

The resin part 39 is filled in the gap between each of the side surfaces of the semiconductor chip 20 and the corresponding tapered inner surface of the concave portion 30y. The width W1 of the surface 30a of the support member 30 can be set to, for example, about 200 μm to about 500 μm. The maximum width W2 of the resin part 39 can be set to, for example, about 1000 μm.

By using the support member 30 having the concave portion 30y of which inner surfaces are tapered, the resin part 39 can be easily filled into the gap between each of the side surfaces of the semiconductor chip 20 and the corresponding tapered inner surface of the concave portion 30y.

First, in order to manufacture semiconductor-package 10D, the support member 30 having the concave portion 30y is fabricated. The width W4 and the depth D4 of the bottom surface of the concave portion 30y can be set to, for example, about 15 mm, respectively. The width W5 and the depth D5 of the open end side of the concave portion 30y can be set to, for example, about 17 mm, respectively. Because the semiconductor chip 20 is accommodated in the concave portion 30y, the size of the concave portion (width W4×depth D4) is set slightly larger than the size of the semiconductor chip 20 (width×depth). Additionally, the thickness of the first member 31 (corresponding to the depth of the concave portion 30y) is set to be approximately equal to the thickness of the semiconductor chip 20 with the double-sided adhesive 38 applied to the back surface thereof.

The concave portion 30y can be formed by forming a resist layer on the support member 30 so as to expose only an area where the concave portion 30y is formed, and applying a blasting process to the support member 30 using the resist layer as a mask. The blasting process is a process of mechanically polishing a surface of a processing object by blasting abrasives onto the processing object with a high-pressure. Thereafter, the process of the first embodiment explained with reference to FIGS. 3 through 12 is performed to complete the semiconductor package 10D illustrated in FIG. 20.

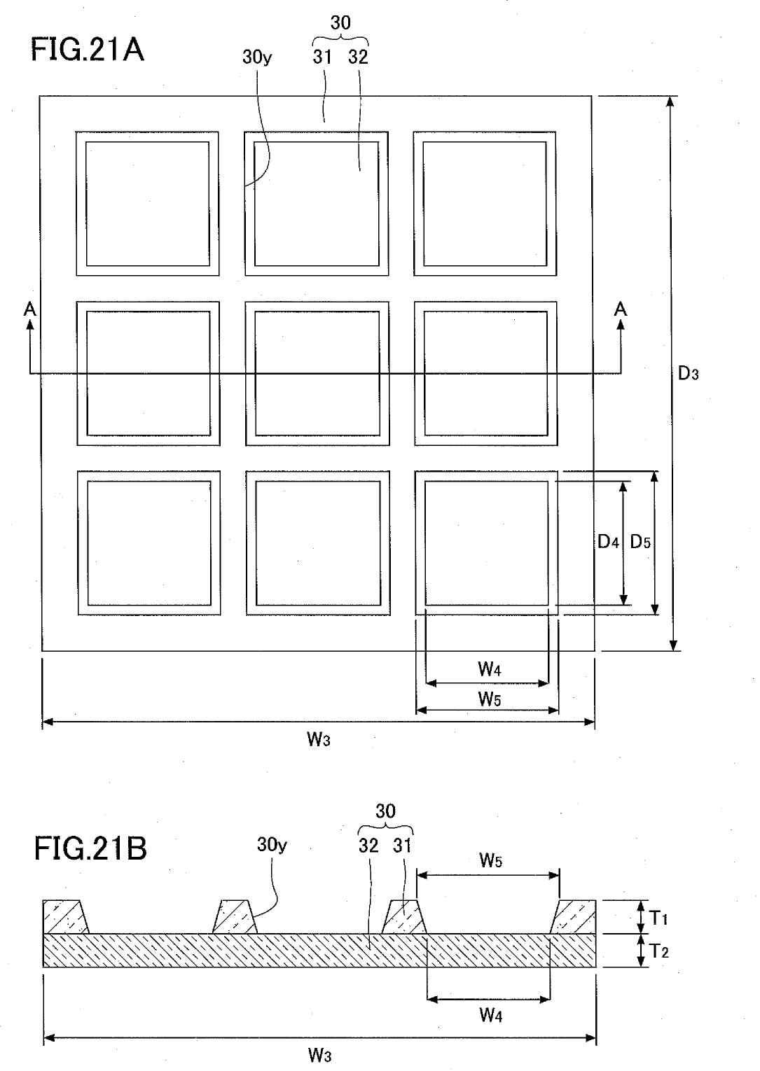

Although each of the inner surfaces indicated by the cross-sectional view of the concave portion 30y in FIG. 20 and FIG. 21 is drawn as a flat surface, the inner surface of the concave portion is not necessarily a flat surface, and may be a curved surface such as a rounded concave surface or the like.

As mentioned above, according to the third embodiment, the same effect as the first embodiment can be obtained, and further the following effect can be obtained. That is, by using the support member having a concave portion having tapered inner surfaces, a resin can be easily filled into the gap formed between each of the side surfaces of the semiconductor chip and the tapered inner surface of the concave portion.

The present invention is not limited to the specifically disclosed embodiments and variations, and various modifications and variations may be made without departing from the scope of the present invention.

For example, in the third embodiment, similar to the second embodiment, a tapered concave portion may be provided to the support member. Additionally, in the third embodiment, similar to the first variation of the first embodiment, the first member and the second member may be joined by plasma bonding. Further, the second variation or the third variation of the first embodiment may be applied to the second embodiment and the third embodiment.

Moreover, the back surface of the support member may be polished or ground after the semiconductor chip is accommodated in the concave portion of the support member in order to cause the back surface of the semiconductor chip to be exposed to the outside environment. Thereby, heat-release performance of the semiconductor chip can be improved. Further, a heat-radiation component such as a heat spreader may be joined to the back surface of the semiconductor chip in order to further improve the heat-release performance of the semiconductor chip.

Moreover, the back surface of the semiconductor chip may be polished or ground when polishing or grinding the back surface of the support member in order to reduce the thickness of the semiconductor package including the semiconductor chip.

All examples and conditional language recited herein are, intended for pedagogical purposes to aid the reader in understanding the principles of the invention and the concepts contributed by the inventor to furthering the art, and are to be construed a being without limitation to such specifically recited examples and conditions, nor does the organization of such examples in the specification relates to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

What is claimed is:

1. A semiconductor package, comprising:
a support member having a concave portion formed in one surface thereof;
a semiconductor chip accommodated in said concave portion so that a circuit formation surface of said semiconductor chip is exposed on a side of said one surface of said support member; and
a wiring structure including a wiring layer electrically connected to said semiconductor chip, the wiring structure being formed on said circuit formation surface of said semiconductor chip and said one surface of said support member,
wherein a portion of said support member including said one surface is made of silicon or borosilicate glass.

2. The semiconductor package as claimed in claim 1, wherein said support member includes a first member and a second member, said first member having a surface serving as said one surface of said support member and another surface opposite to said one surface, said second member being directly joined to said another surface of said first member.

3. The semiconductor package as claimed in claim 2, wherein said first member is made of a material selected from a group consisting of silicon and borosilicate, and said second member is made of a material selected from a group consisting of silicon, borosilicate glass and metal.

4. The semiconductor package as claimed in claim 3, wherein said first member and said second member are directly joined to each other by anodic bonding or plasma bonding.

5. The semiconductor package as claimed in claim 2, wherein one of said first member and said second member is made of borosilicate glass, and said first member and said second member are joined to each other by anodic bonding.

6. The semiconductor package as claimed in claim 1, wherein a resin part is formed in a gap between a side surface of said semiconductor chip and an inner side surface of said concave portion facing said side surface of said semiconductor chip.

7. The semiconductor package as claimed in claim 6, wherein said resin part fills a portion of said gap, and an insulation resin included in said wiring structure fills a rest of said gap.

8. The semiconductor package as claimed in claim 1, wherein an insulation resin included in said wiring structure fills an entire gap between a side surface of said semiconductor chip and an inner side surface of said concave portion facing said side surface of said semiconductor chip.

9. The semiconductor package as claimed in claim 1, wherein inner side surfaces of said concave portion is tapered so that an area of opening at an open end side of said concave portion is larger than an area of a bottom surface of said concave portion.

10. The semiconductor package as claimed in claim 1, wherein said support member includes a first member and a second member, said first member having a planar shape and having a penetrating opening, said second member having a planar shape, and wherein said first member is laminated on said second member, and said concave portion is formed by a top surface of said second member exposed in said penetrating opening and inner surfaces of said penetrating opening.

11. A manufacturing method of a semiconductor package, comprising:
preparing a support member having a concave portion formed in one surface thereof, a portion of said support member including said one surface being made of silicon or borosilicate glass;
accommodating a semiconductor chip in said concave portion of said support member so that a circuit formation surface of said semiconductor chip is exposed on a side of said one surface of said support member; and
forming a wiring structure on said circuit formation surface of said semiconductor chip and said one surface of said support member, said wiring structure including a wiring layer electrically connected to said semiconductor chip.

12. The manufacturing method of a semiconductor package as claimed in claim 11, wherein said preparing a support member includes joining a first member and a second member to each other by direct bonding, said first member having a surface serving as said one surface of said support member and another surface opposite to said one surface, said second member being directly joined to said another surface of said first member.

13. The manufacturing method of a semiconductor package as claimed in claim 12, wherein said preparing a support member includes making said first member by a material selected from a group consisting of silicon and borosilicate, and making said second member by a material selected from a group consisting of silicon, borosilicate glass and metal.

14. The manufacturing method of a semiconductor package as claimed in claim 13, wherein said preparing a support member includes directly joining said first member and said second member to each other by anodic bonding or plasma bonding.

15. The manufacturing method of a semiconductor package as claimed in claim 12, wherein said preparing a support member includes making one of said first member and said second member by borosilicate glass, and joining said first member and said second member to each other by anodic bonding.

16. The manufacturing method of a semiconductor package as claimed in claim 11, wherein further comprising forming a resin part in a gap between a side surface of said semiconductor chip and an inner side surface of said concave portion facing said side surface of said semiconductor chip.

17. The manufacturing method of a semiconductor package as claimed in claim 16, further comprising filling an insulation resin included in said wiring structure into a portion of said gap where said resin part is not filled.

18. The manufacturing method of a semiconductor package as claimed in claim 11, further comprising filling an insulation resin included in said wiring structure into an entire gap between a side surface of said semiconductor chip and an inner side surface of said concave portion facing said side surface of said semiconductor chip.

19. The manufacturing method of a semiconductor package as claimed in claim 11, wherein said preparing a support member includes forming said concave portion having tapered side surfaces so that an area of opening at an open end side of said concave portion is larger than an area of a bottom surface of said concave portion.

20. The manufacturing method of a semiconductor package as claimed in claim 11, wherein said preparing a support member includes laminating a first member on a second member, said first member having a planar shape and having a penetrating opening, said second member having a planar shape so as to form a concave portion by a top surface of said second member exposed in said penetrating opening and inner surfaces of said penetrating opening.
